(19) United States
(12) Patent Application Publication
(10) Pub. No.: US 2026/0255816 A1
(43) Pub. Date: Aug. 27, 2026

(54) Display Panel and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Zhiwen CHU, Beijing (CN); Fan HE, Beijing (CN); Hongwei MA, Beijing (CN); Xiaoqing SHU, Beijing (CN); Biao LIU, Beijing (CN); Yi ZHANG, Beijing (CN); Yiding WANG, Beijing (CN); Liheng WEI, Beijing (CN)

(21) Appl. No.: 18/992,584

(22) PCT Filed: Aug. 16, 2024
(86) PCT No.: PCT/CN2024/112643

§ 371 Date: Jan. 9, 2025

(30) Foreign Application Priority Data
Sep. 28, 2023 (WO) PCT/CN2023/122646
Feb. 19, 2024 (CN) 202410186076.1

(51) Int. Cl. H10K 59/131; H10K 59/126; H10K 59/40; H10K 59/80

(52) U.S. Cl. CPC H10K 59/131; H10K 59/126; H10K 59/40; H10K 59/8723; H10K 59/873

(57) ABSTRACT

Disclosed is a display panel including a base substrate, a plurality of sub-pixels, a plurality of data lines, a plurality of data fan-out lines, and a first light shielding structure. The base substrate includes a display region and a first bezel region located on at least one side of the display region. The first bezel region includes a first fan-out region and a bending region sequentially disposed along a direction away from the display region. The plurality of sub-pixels and the plurality of data lines are located in the display region, and are electrically connected. The plurality of data fan-out lines are electrically connected with the plurality of data lines, and are configured to provide data signals to the plurality of sub-pixels of the display region. The first light shielding structure is located on a side of the plurality of data fan-out lines away from the base substrate.

### CROSS-REFERENCE TO RELATED APPLICATIONS

The present application is a U.S. National Phase Entry of International Application No. PCT/CN2024/112643 having an international filing date of Aug. 16, 2024, which claims priorities to International Application No. PCT/CN2023/122646 and an invention name “Display Panel and Display Apparatus” having an international filing date of Sep. 28, 2023, and Chinese Patent Application No. 202410186076.1 and an invention name “Display Panel and Display Apparatus” filed to the CNIPA on Feb. 19, 2024, contents of the above-identified applications should be understood to be incorporated into the present application by reference.

### TECHNICAL FIELD

The present disclosure relates to, but is not limited to, the field of display technologies, in particular to a display panel and a display apparatus.

### BACKGROUND

An Organic Light Emitting Diode (OLED) and a Quantum dot Light Emitting Diode (QLED) are active light emitting display devices, and have advantages of self-illumination, a wide viewing angle, a high contrast ratio, low power consumption, an extremely high reaction speed, lightness and thinness, flexibility, and a low cost, etc. With continuous development of display technologies, a display apparatus in which an OLED is used as a light emitting device and signal control is performed by a Thin Film Transistor (TFT) has become a mainstream product in the field of display at present.

### SUMMARY

The following is a summary of subject matters described herein in detail. The summary is not intended to limit the protection scope of claims.

Embodiments of the present application provide a display panel and a display apparatus.

In one aspect, an embodiment provides a display panel including: a base substrate, a plurality of sub-pixels, a plurality of data lines, a plurality of data fan-out lines, and a first light shielding structure. The base substrate includes a display region and a first bezel region located on at least one side of the display region. The first bezel region includes: a first fan-out region and a bending region disposed in sequence along a direction away from the display region. The plurality of sub-pixels and the plurality of data lines are located in the display region, and the plurality of data lines are electrically connected with the plurality of sub-pixels. The plurality of data fan-out lines are located in the first fan-out region, and electrically connected with the plurality of data lines, and are configured to provide data signals to the plurality of sub-pixels of the display region. The first light shielding structure is located in the first fan-out region, the first light shielding structure is located on a side of the plurality of data fan-out lines away from the base substrate, and an orthographic projection of the first light shielding structure on the base substrate is partially overlapped with orthographic projections of the plurality of data fan-out lines on the base substrate.

In some exemplary implementation modes, the display panel further includes an isolation slot located in the first fan-out region. The first light shielding structure is located on a side of the isolation slot close to the display region, and a distance between the orthographic projection of the first light shielding structure on the base substrate and an orthographic projection of the isolation slot on the base substrate is greater than 0.

In some exemplary implementation modes, the display panel further includes: a first dam spacer at least partially located within the isolation slot and a second dam spacer at least partially located within the isolation slot, the second dam spacer is located on a side of the first dam spacer away from the display region. At least one data fan-out line of the plurality of data fan-out lines includes a first extension segment and a second extension segment connected with each other, the first extension segment is located on a side of the second extension segment close to the display region, and extension directions of the first extension segment and the second extension segment intersect; a distance between first extension segments of two adjacent data fan-out lines is less than or equal to a distance between second extension segments of the two adjacent data fan-out lines. A connection position of the first extension segment and the second extension segment is located on a side of the second dam spacer close to the display region.

In some exemplary implementation modes, a minimum included angle between an orthographic projection of the first extension segment of the at least one data fan-out line on the base substrate and an orthographic projection of the first dam spacer on the base substrate is less than or equal to a minimum included angle between an orthographic projection of the second extension segment on the base substrate and the orthographic projection of the first dam spacer on the base substrate.

In some exemplary implementation modes, the first light shielding structure includes at least one light shielding sheet, a length of the light shielding sheet in a direction from the display region to the first bezel region is smaller than a length extending along an edge of the display region, and the light shielding sheet is provided with a plurality of vias penetrating through the light shielding sheet along a direction perpendicular to the base substrate.

In some exemplary implementation modes, the display panel further includes a first bezel power supply line located in the first fan-out region, the first bezel power supply line is configured to provide a first voltage signal to a plurality of sub-pixels of the display region; the first light shielding structure is connected with the first bezel power supply line.

In some exemplary implementation modes, the first light shielding structure includes at least one light shielding sheet, and the at least one light shielding sheet and the first bezel power supply line are of an interconnected integral structure.

In some exemplary implementation modes, the display panel further includes a second bezel power supply line located in the first fan-out region, the second bezel power supply line is configured to provide a second voltage signal to a plurality of sub-pixels of the display region, the second voltage signal is greater than the first voltage signal. The second bezel power supply line is located on a side of the first bezel power supply line close to the base substrate and located on a side of the plurality of data fan-out lines away from the base substrate, and an orthographic projection of the second bezel power supply line on the base substrate is partially overlapped with an orthographic projection of the first bezel power supply line on the base substrate.

In some exemplary implementation modes, the display panel further includes at least one planarization layer, and a surface of the first light shielding structure close to the base substrate is in contact with a planar surface of the planarization layer.

In some exemplary implementation modes, in a direction perpendicular to the display panel, the display panel includes at least: a first source-drain metal layer, a second source-drain metal layer, and a third source-drain metal layer sequentially disposed on the base substrate; the first light shielding structure is located on at least one of following film layers: the first source-drain metal layer, the second source-drain metal layer, and the third source-drain metal layer.

In some exemplary implementation modes, the display panel further includes: an encapsulation layer and a light shielding layer; the encapsulation layer is located on a side of the first light shielding structure away from the base substrate, and the light shielding layer is located on a side of the encapsulation layer away from the base substrate; a distance between an orthographic projection of the light shielding layer on the base substrate and the orthographic projection of the first light shielding structure on the base substrate is greater than 0; a material of the light shielding layer is a light-opaque organic material.

In some exemplary implementation modes, the display panel further includes: a second light shielding structure located in the first fan-out region and located on a side of the first light shielding structure away from the display region; and the second light shielding structure is located on a side of the first light shielding structure away from the base substrate.

In some exemplary implementation modes, in a direction perpendicular to the display panel, the display panel includes a plurality of display conductive layers and at least one touch conductive layer sequentially disposed on the base substrate. The first light shielding structure is located in one display conductive layer of the plurality of display conductive layers, and the second light shielding structure is located in the at least one touch conductive layer.

In some exemplary implementation modes, the display panel further includes a plurality of data transfer lines located in the display region, and at least one data transfer line of the plurality of data transfer lines includes: a first transfer segment extending along a first direction and a second transfer segment extending along a second direction, the plurality of data lines extend along the second direction, and the first direction intersects with the second direction; at least one data line of the plurality of data lines is connected with the first transfer segment of the data transfer line, the second transfer segment of the data transfer line is connected with the data fan-out lines, and the data line is located on a side of the second transfer segment of the connected data transfer line close to an edge of the display panel in the first direction.

In some exemplary implementation modes, the display panel further includes a plurality of sets of data bending lines located in the bending region and disposed separately, the plurality of data fan-out lines include a plurality of sets of data fan-out lines, and the plurality of sets of data fan-out lines are connected with the plurality of sets of data bending lines in a one-to-one correspondence.

In another aspect, an embodiment provides a display apparatus, including the aforementioned display panel.

Other features and advantages of the present application will be set forth in the specification which follows, and in part will become apparent from the specification, or may be learned by practice of the present application. Other advantages of the present application may be achieved and obtained through solutions described in the specification and drawings.

### BRIEF DESCRIPTION OF DRAWINGS

Accompanying drawings are used for providing an understanding of technical solutions of the present application and form a part of the specification, are used for explaining the technical solutions of the present application together with embodiments of the present application, and do not constitute limitations on the technical solutions of the present application.

FIG. 1 is a schematic diagram of a display panel according to at least one embodiment of the present disclosure.

FIG. 2 is a schematic partial sectional view of a display region according to at least one embodiment of the present disclosure.

FIG. 3 is a schematic partial structural diagram of a display region and a first fan-out region according to at least one embodiment of the present disclosure.

FIG. 4A is a schematic diagram of a trace arrangement of a first fan-out region and a bending region according to at least one embodiment of the present disclosure.

FIG. 4B and FIG. 4C are schematic partial structural diagrams of the first fan-out region in FIG. 4A.

FIG. 5 is a schematic partial sectional view along a Q-Q′ direction in FIG. 4A.

FIG. 6A is a partial enlarged schematic diagram of a region S1 in FIG. 4A.

FIG. 6B is a schematic diagram of a first gate metal layer, a second gate metal layer, and a first source-drain metal layer in FIG. 6A.

FIG. 6C is a schematic diagram of the first gate metal layer, the second gate metal layer, the first source-drain metal layer, and a second source-drain metal layer in FIG. 6A.

FIG. 6D is a schematic diagram of the first gate metal layer, the second gate metal layer, and a third source-drain metal layer in FIG. 6A.

FIG. 7 is another schematic partial sectional view of a first fan-out region according to at least one embodiment of the present disclosure.

FIG. 8 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the accompanying drawings, not to indicate or imply that a referred apparatus or element must have a specific orientation and be structured and operated with the specific orientation but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations. Herein, a “connection” includes an “electrical connection”, and the “electrical connection” includes a case where constituent elements are connected together through an element with a certain electrical effect. The “element with a certain electrical effect” is not particularly limited as long as electrical signals between the connected constituent elements may be transmitted. Examples of the “element with a certain electrical effect” not only include an electrode and a wiring, but also include a switching element such as a transistor, a resistor, an inductor, a capacitor, another element with various functions, etc.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “about” and “substantially” refer to that a boundary is not defined strictly and a case within a range of process and measurement errors is allowed.

In the present specification, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends along a B direction” in the present specification always means “a main body portion of A extends along a B direction”.

“A and B are of a same layer structure” mentioned in the present specification means that A and B are formed simultaneously through a same patterning process. A “same layer” does not always mean that thicknesses of layers or heights of layers are the same in a section diagram. “An orthographic projection of A contains an orthographic projection of B” means that the orthographic projection of B falls within a range of the orthographic projection of A, or the orthographic projection of A covers the orthographic projection of B.

A display panel usually includes a display region and a non-display region, the display region is used for displaying a required picture, and the non-display region is used for providing a circuit structure for controlling working of the display region, and the circuit structure includes, for example, a display drive circuit, various traces, a flexible circuit board, and the like. The non-display region may also be provided with various structures for ensuring screen encapsulation, such as dam adhesive. Due to existence of various traces on an uneven film layer of the display panel, after light is reflected and refracted between a plurality of film layers of the non-display region, a user can still see light reflected from the non-display region when the display panel is in a screen-off state, thus forming a light leakage phenomenon (or bottom reflection phenomenon). In order to prevent light leakage in the non-display region of the display panel, for example, a light shielding layer may be coated on the non-display region to shield light. However, the light shielding layer has problems such as fitting tolerance and manufacturing tolerance, and an edge of the light shielding layer has a certain distance from the display region to meet needs of a whole machine. Since there is a light leakage region which is not shielded by the light shielding layer between the edge of the light shielding layer close to the display region and the display region, light in the light leakage region is not shielded, thus there is light coming out from the light leakage region. Moreover, with users' demand for portable electronic products (such as mobile phones), products with narrow lower bezels are increasingly favored by consumers. The narrower the bezel of products with narrow lower bezels, the smaller the wiring space, and shortening a trace interval will further increase a light leakage phenomenon of a lower bezel.

An embodiment provides a display panel including: a base substrate, a plurality of sub-pixels, a plurality of data lines, a plurality of data fan-out lines, and a first light shielding structure. The base substrate includes a display region and a first bezel region located on at least one side of the display region. The first bezel region includes a first fan-out region and a bending region disposed in sequence along a direction away from the display region. The plurality of sub-pixels and the plurality of data lines are located in the display region, and the plurality of data lines are electrically connected with the plurality of sub-pixels. The plurality of data fan-out lines are located in the first fan-out region, and are electrically connected with the plurality of data lines, and are configured to provide data signals to the plurality of sub-pixels of the display region. The first light shielding structure is located in the first fan-out region and is located on a side of the plurality of data fan-out lines away from the base substrate. An orthographic projection of the first light shielding structure on the base substrate is partially overlapped with orthographic projections of the plurality of data fan-out lines on the base substrate. For example, the orthographic projection of the first light shielding structure on the base substrate may be partially overlapped with an orthographic projection of each data fan-out line on the base substrate; or, the orthographic projection of the first light shielding structure on the base substrate may be partially overlapped with orthographic projections of some data fan-out lines of the plurality of data fan-out lines on the base substrate.

In the display panel according to the embodiment, by disposing the first light shielding structure in the first fan-out region, a light leakage region of the first fan-out region is shielded by using the first light shielding structure, so that a light leakage phenomenon of the first bezel region of the display panel may be improved.

In some exemplary implementation modes, a surface of the first light shielding structure close to the base substrate is in contact with a planarization layer. For example, the planarization layer may be an organic insulation layer and may have a planar surface. The present example may ensure flatness of a surface of the first light shielding structure, thereby improving a light leakage phenomenon caused by reflection and refraction of an uneven film layer or a trace disposed on the uneven film layer. In the present example, flatness may refer to surface fluctuation that may be observed under a macro scale, for example, a naked eye or an optical microscope. The flatness may also refer to microscopic surface roughness and flatness of a corresponding cross-section observed by means of microscopic morphology characterization and instruments, such as a Scanning Electron Microscope (SEM) or an Atomic Force Microscope (AFM) under a micro scale. A planar surface means that there is no obvious fluctuation on the surface under a corresponding scale.

In some exemplary implementation modes, the display panel may further include an isolation slot located in the first fan-out region, the first light shielding structure is located on a side of the isolation slot close to the display region, and a distance between an orthographic projection of the first light shielding structure on the base substrate and an orthographic projection of the isolation slot on the base substrate is greater than 0. In other words, the orthographic projection of the first light shielding structure on the base substrate may not be partially overlapped with the orthographic projection of the isolation slot on the base substrate. In the present example, the first light shielding structure is disposed to avoid the isolation slot, and surface flatness of the first light shielding structure may be ensured, thereby improving light leakage phenomenon caused by reflection and refraction of an uneven film layer or a trace disposed on the uneven film layer.

In some exemplary implementation modes, the display panel may further include a first dam spacer located at least partially within the isolation slot and a second dam spacer located at least partially within the isolation slot, and the second dam spacer may be located on a side of the first dam spacer away from the display region. At least one data fan-out line may include a first extension segment and a second extension segment connected with each other, the first extension segment is located on a side of the second extension segment close to the display region. Extension directions of the first extension segment and the second extension segment intersect. A distance between first extension segments of two adjacent data fan-out lines may be less than or equal to a distance between second extension segments of two adjacent data fan-out lines. A connection position of the first extension segment and the second extension segment may be located on a side of the second dam spacer close to the display region. In some examples, a minimum included angle between an orthographic projection of the first extension segment of the at least one data fan-out line on the base substrate and an orthographic projection of the first dam spacer on the base substrate may be less than or equal to a minimum included angle between an orthographic projection of the second extension segment on the base substrate and the orthographic projection of the first dam spacer on the base substrate. For example, the first extension segment may be an oblique extension segment, and the second extension segment may be a vertical extension segment. In the present example, by adjusting the connection position of the first extension segment and the second extension segment to be located on the side of the second dam spacer close to the display region, an interval between adjacent data fan-out lines may be increased, which is beneficial to reduce reflection between adjacent data fan-out lines, thereby reducing a risk of light leakage caused by reflection.

In some exemplary implementation modes, the display panel may further include a first bezel power supply line located in the first fan-out region. The first bezel power supply line may be configured to provide a first voltage signal to a plurality of sub-pixels of the display region. The first light shielding structure may be connected with the first bezel power supply line. In some examples, the first light shielding structure may include at least one light shielding sheet, and the at least one light shielding sheet and the first bezel power supply line may be of an interconnected integral structure. For example, the first light shielding structure and the first bezel power supply line may be located on a display conductive layer (e.g., a third source-drain metal layer). In this example, by providing the first light shielding structure to be connected with the first bezel power supply line, the first light shielding structure prepared by using a conductive material may be prevented from floating in the first fan-out region and affecting performance of the display panel. However, the embodiment is not limited thereto. In other examples, a non-conductive material may be adopted for the first light shielding structure, for example, a light-opaque organic material may be adopted.

In some exemplary implementation modes, the display panel may further include a second bezel power supply line located in the first fan-out region, the second bezel power supply line may be configured to provide a second voltage signal to the plurality of sub-pixels of the display region, the second voltage signal may be greater than the first voltage signal, for example, the second voltage signal may be a high-level signal, and the first voltage signal may be a low-level signal. The second bezel power supply line may be located on a side of the first bezel power supply line close to the base substrate and located on a side of the plurality of data fan-out lines away from the base substrate. An orthographic projection of the second bezel power supply line on the base substrate may be partially overlapped with an orthographic projection of the first bezel power supply line on the base substrate. In some examples, the first light shielding structure may be connected with the second bezel power supply line to prevent the first light shielding structure from floating and affecting performance of the display panel.

In some exemplary implementation modes, the display panel may further include an encapsulation layer and a light shielding layer. The encapsulation layer may be located on a side of the first light shielding structure away from the base substrate, and the light shielding layer may be located on a side of the encapsulation layer away from the base substrate. A distance between an orthographic projection of the light shielding layer on the base substrate and an orthographic projection of the first light shielding structure on the base substrate may be greater than 0. In other words, orthographic projections of the light shielding layer and the first light shielding structure on the base substrate may not be overlapped. A material of the light shielding layer may be different from a material of the first light shielding structure. For example, the material of the light shielding layer may be a light-opaque organic material, such as ink. The material of the first light shielding structure may be a conductive material. Or, the material of the light shielding layer may be ink, and the material of the first light shielding structure may be a black resin material. In this example, through a matching arrangement of the first light shielding structure and the light shielding layer, a light leakage region of the first fan-out region may be shielded, thereby improving a light leakage problem of the display panel.

In some exemplary implementation modes, the display panel may further include a second light shielding structure located in the first fan-out region. The second light shielding structure may be located on a side of the first light shielding structure away from the display region, and the second light shielding structure may be located on a side of the first light shielding structure away from the base substrate. In some examples, in a direction perpendicular to the display panel, the display panel may include a plurality of display conductive layers and at least one touch conductive layer sequentially disposed on the base substrate. The first light shielding structure may be located in one of the display conductive layers, for example, may be located in one of the plurality of display conductive layers closest to the touch conductive layer. The second light shielding structure may be located in the at least one touch conductive layer. In this example, through a matching arrangement of the first light shielding structure and the second light shielding structure, the light leakage region of the first fan-out region may be shielded, thereby improving the light leakage problem of the display panel.

Solutions of the embodiments will be described below through some examples.

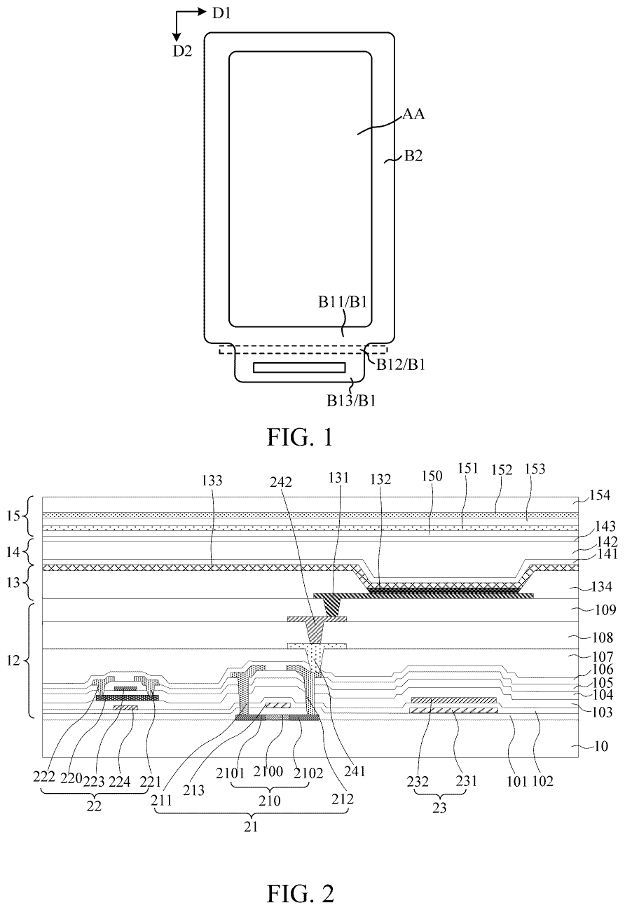

FIG. 1 is a schematic diagram of a display panel according to at least one embodiment of the present disclosure. In some examples, as shown in FIG. 1, the display panel may include a display region AA and a bezel region (which may also be referred to as a non-display region) located at a periphery of the display region AA. The bezel region may include a first bezel region B1 located on a side of the display region AA and a second bezel region B2 located on remaining sides of the display region AA. The first bezel region B1 may be located on a side of the display region AA along the second direction D2. The first bezel region B1 may be communicated with the second bezel region B2. For example, the first bezel region B1 may be a lower bezel region of the display panel, and the second bezel region B2 may include: a left bezel region, a right bezel region, and an upper bezel region of the display panel.

In some examples, as shown in FIG. 1, the display region AA may be a planar region including a plurality of sub-pixels that form a pixel array. The plurality of sub-pixels may be configured to display dynamic pictures or static images. The display region AA may also be referred to as an Active Area. In some examples, the display region AA may be rectangular. However, the present embodiment is not limited thereto. For example, the display region AA may be circular or oval. In some examples, the display panel may be a flexible display panel, and accordingly the display panel may be deformable, for example, may be crimped, bent, folded, or curled.

In some examples, as shown in FIG. 1, the display region AA may include a display structure layer disposed on a base substrate, or may include a display structure layer and a touch structure layer disposed sequentially on the base substrate. For example, in the display panel, a touch structure may be integrated to form a structure of Touch on Thin film Encapsulation (Touch on TFE for short). The structure of Touch on TFE mainly includes a Flexible Multi-Layer On Cell (FMLOC) structure and a Flexible Single-Layer On Cell (FSLOC) structure. The FMLOC structure is based on a working principle of mutual capacitance detection. Generally, a drive (Tx) electrode and a sensing (Rx) electrode are formed by using two layers of metal, and a drive chip (IC) achieves a touch action by detecting a mutual capacitance between the drive electrode and the sensing electrode. The FSLOC structure is based on a working principle of self-capacitance (or voltage) detection. Generally, a touch electrode is formed by using a single layer of metal, and an integrated circuit achieves a touch action by detecting a self-capacitance (or voltage) of the touch electrode.

In some examples, the display structure layer may include a plurality of sub-pixels, a plurality of gate lines, and a plurality of data lines. The plurality of gate lines may extend along a first direction D1, and the plurality of data lines may extend along a second direction D2. Orthogonal projections of the plurality of gate lines on the base substrate may intersect with orthogonal projections of the plurality of data lines on the base substrate, thereby forming a plurality of sub-pixel regions. One sub-pixel may be disposed within one sub-pixel region. The plurality of data lines may be electrically connected with the plurality of sub-pixels and the plurality of data lines may be configured to provide data signals to the plurality of sub-pixels. The plurality of gate lines may be electrically connected with the plurality of sub-pixels and the plurality of gate lines may be configured to provide gate drive signals to the plurality of sub-pixels. For example, the gate drive signals may include a scan signal, or may include a scan signal and a light emitting control signal, or may include a scan signal, a reset control signal, and a light emitting control signal. In some examples, the first direction D1 may be an extension direction (e.g., a row direction) of a gate line within the display region AA. The second direction D2 may be an extension direction (e.g., a column direction) of a data line within the display region AA. The first direction D1 and the second direction D2 may intersect with each other, for example, they may be perpendicular to each other.

In some examples, one display pixel of the display region AA may include three sub-pixels, and the three sub-pixels may be a first sub-pixel emitting light of a first color (e.g., red light), a second sub-pixel emitting light of a second color (e.g., green light), and a third sub-pixel emitting light of a third color (e.g., blue light), respectively. However, the present embodiment is not limited thereto. In some examples, one pixel unit may include four sub-pixels, which may be a sub-pixel emitting red light, a sub-pixel emitting green light, a sub-pixel emitting blue light, and a sub-pixel emitting white light, respectively. For another example, one pixel unit may include four sub-pixels, which may include one sub-pixel emitting red light, one sub-pixel emitting blue light, and two sub-pixels emitting green light.

In some examples, one sub-pixel may include a pixel circuit and a light emitting element electrically connected with the pixel circuit. The pixel circuit may include a plurality of transistors and at least one capacitor. For example, the pixel circuit may have a 3T1C, 4T1C, 5T1C, 5T2C, 6T1C, 7T1C, or 8T1C structure. In the above-mentioned circuit structures, T refers to a thin film transistor, C refers to a capacitor, a number before T represents a quantity of thin film transistors in the circuit, and a number before C represents a quantity of capacitors in the circuit. In some examples, a plurality of transistors in the pixel circuit may include a P-type transistor and an N-type transistor. In other examples, the plurality of transistors in the pixel circuit may be P-type transistors, or may be N-type transistors. Using a same type of transistor in the pixel circuit may simplify a process flow, reduce a process difficulty of the display panel, and improve a yield of products.

In some examples, a shape of the light emitting element of the sub-pixel may be a rectangle, a rhombus, a pentagon, or a hexagon. When one display pixel includes three sub-pixels, light emitting elements of the three sub-pixels may be arranged side by side horizontally, side by side vertically, or in a manner of a Chinese character “ [symbol] ”. When one display pixel includes four sub-pixels, light emitting elements of the four sub-pixels may be arranged side by side horizontally, side by side vertically, or in a manner to form a square. However, the present embodiment is not limited thereto.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected with a corresponding pixel circuit. However, the present embodiment is not limited thereto.

FIG. 2 is a schematic partial sectional view of a display region according to at least one embodiment of the present disclosure. FIG. 2 is illustrated by taking a structure of one sub-pixel of the display region as an example. In some examples, as shown in FIG. 2, in a direction perpendicular to the display panel, the display region of the display panel may include a base substrate 10, and a circuit structure layer 12, a light emitting structure layer 13, an encapsulation structure layer 14, and a touch structure layer 50 that are sequentially disposed on the base substrate 10. The display structure layer may include at least a circuit structure layer 12 and a light emitting structure layer 13. The circuit structure layer 12 may include at least pixel circuits of a plurality of sub-pixels, and a pixel circuit of each sub-pixel may include a plurality of transistors and at least one capacitor. The light emitting structure layer 13 may include at least light emitting elements of a plurality of sub-pixels.

In some examples, FIG. 2 is illustrated by taking one first-type transistor 21, one second-type transistor 22, and one capacitor 23 included in each sub-pixel as an example. Herein, the first-type transistor 21 may be a low temperature poly silicon thin film transistor, and the second-type transistor 22 may be an oxide thin film transistors.

In some examples, the circuit structure layer 12 of the display region may include: a first semiconductor layer, a first gate metal layer, a second gate metal layer, a second semiconductor layer, a third gate metal layer, a first source-drain metal layer, a second source-drain metal layer, and a third source-drain metal layer disposed on the base substrate 10. A plurality of display conductive layers of the present example may include: a first gate metal layer, a second gate metal layer, a third gate metal layer, a first source-drain metal layer, a second source-drain metal layer, and a third source-drain metal layer. A first Gate Insulation (GI) layer 101 may be disposed between the first semiconductor layer and the first gate metal layer, and a second gate insulation layer 102 may be disposed between the first gate metal layer and the second gate metal layer; a third gate insulation layer 103 may be disposed between the second gate metal layer and the second semiconductor layer; a fourth gate insulation layer 104 may be disposed between the second semiconductor layer and the third gate metal layer; an interlayer dielectric layer 105 may be disposed between the third gate metal layer and the first source-drain metal layer; a Passivation (PVX) layer 106 and a first Planarization (PLN) layer 107 may be disposed between the first source-drain metal layer and the second source-drain metal layer, and the first planarization layer 107 may be located on a side of the passivation layer 106 away from the base substrate 10; a second planarization layer 108 may be disposed between the second source-drain metal layer and the third source-drain metal layer; a third planarization layer 109 may be disposed on a side of the third source-drain metal layer away from the base substrate 10. The first gate insulation layer 101, the second gate insulation layer 102, the third gate insulation layer 103, the fourth gate insulation layer 104, the interlayer dielectric layer 105, and the passivation layer 106 may be inorganic insulation layers, and the first planarization layer 107, the second planarization layer 108, and the third planarization layer 109 may be organic insulation layers. However, the present embodiment is not limited thereto. In other examples, a side of the first semiconductor layer close to the base substrate may also be provided with a buffer layer, and the buffer layer may prevent harmful substances in the base substrate from intruding into interior of the display panel, and may also increase adhesion of a film layer in the display panel on the base substrate. In other examples, a Bottom Shielding Metal (BSM) layer may be provided on a side of the buffer layer close to the base substrate, and the bottom shielding metal layer may be configured to at least partially cover an active layer of a transistor of a pixel circuit to avoid an influence of external light on performance of the transistor. In other examples, the passivation layer may be omitted between the first source-drain metal layer and the second source-drain metal layer, and only the first planarization layer may be provided between the first source-drain metal layer and the second source-drain metal layer.

In some examples, as shown in FIG. 2, the first semiconductor layer of the display region may include at least a first active layer 210 of the first-type transistor 21. The first active layer 210 of the first-type transistor 21 may include: a first region 2101, a second region 2102, and a channel region 2100 located between the first region 2101 and the second region 2102. The first gate metal layer may at least include: a first gate 213 of the first-type transistor 21, and a first electrode plate 231 of the capacitor 23. An orthographic projection of the first gate 213 of the first-type transistor 21 on the base substrate 10 may cover an orthographic projection of the channel region 2100 of the first active layer 210 on the base substrate 10. The second gate metal layer may at least include: a second electrode plate 232 of the capacitor 23, a third gate 224 of the second-type transistor 22. Orthographic projections of the second electrode plate 232 and the first electrode plate 231 of the capacitor 23 on the base substrate 10 may be at least partially overlapped, for example, the two may coincide. The second semiconductor layer may at least include a second active layer 220 of the second-type transistor 22. The third gate metal layer may at least include a second gate 223 of the second-type transistor 22. An orthographic projection of the second gate 223 of the second-type transistor 22 on the base substrate 10 and an orthographic projection of the second active layer 220 on the base substrate 10 may be partially overlapped. An orthographic projection of the third gate 224 of the second-type transistor 22 on the base substrate 10 and an orthographic projection of the second active layer 220 on the base substrate 10 may be partially overlapped. The third gate 224 may be a bottom gate of the second-type transistor 22, and the second gate 223 may be a top gate of the second-type transistor 22.

In some examples, as shown in FIG. 2, a first source-drain metal layer of the display region may at least include: a first source electrode 211 and a first drain electrode 212 of the first-type transistor 21, and a second source electrode 221 and a second drain electrode 222 of the second-type transistor 22. The interlayer dielectric layer 105 may be provided with a plurality of pixel vias (including, for example, a first pixel via, a second pixel via, a third pixel via, and a fourth pixel via) in the display region, and the interlayer dielectric layer 105, the fourth gate insulation layer 104, the third gate insulation layer 103, the second gate insulation layer 102, and the first gate insulation layer 101 in the first pixel via may be removed to expose at least part of a surface of a first region 2101 of the first active layer 210. The interlayer dielectric layer 105, the third gate insulation layer 104, the third gate insulation layer 103, the second gate insulation layer 102, and the first gate insulation layer 101 in the second pixel via may be removed to expose at least part of a surface of a second region 2102 of the first active layer 210. The interlayer dielectric layer 105, the fourth gate insulation layer 104, and the third gate insulation layer 103 in the third pixel via and the fourth pixel via may be removed to expose at least part of surfaces of two ends of the second active layer 220. The first source electrode 211 of the first-type transistor 21 may be electrically connected with the first region 2101 of the first active layer 210 through the first pixel via, and the first drain electrode 212 may be electrically connected with the second region 2102 of the first active layer 210 through the second pixel via. The second source electrode 221 of the second-type transistor 22 may be electrically connected with one end of the second active layer 220 through the third pixel via, and the second drain electrode 222 of the second-type transistor 22 may be electrically connected with the other end of the second active layer 220 through the fourth pixel via. The second source-drain metal layer may at least include a first transfer electrode 241. The first transfer electrode 241 may be electrically connected with the first drain electrode 212 of the first-type transistor 21 of the pixel circuit through a fifth pixel via opened in the passivation layer 106 and the first planarization layer 107. The third source-drain metal layer may include at least a second transfer electrode 242. The second transfer electrode 242 may be connected with the first transfer electrode 241 through a sixth pixel via opened in the second planarization layer 108. In this example, an electrical connection between the pixel circuit and the light emitting element may be achieved through the first transfer electrode 241 and the second transfer electrode 242.

In some examples, a gate line of the display region may be located, for example, in the first gate metal layer and the third gate metal layer, a data line of the display region may be located, for example, in the second source-drain metal layer, a high-potential power supply line of the display region may be located, for example, in the second source-drain metal layer, and a low-potential power supply line of the display region may be located, for example, in the third source-drain metal layer. The present embodiment is not limited thereto.

In some examples, as shown in FIG. 2, the light emitting structure layer 13 may include a pixel definition layer 134 and a plurality of light emitting elements. For example, each light emitting element may include a first electrode 131, an organic emitting layer 132, and a second electrode 133 which are stacked. The first electrode 131 of the light emitting element may be an anode, the first electrode 131 may be provided on the third planarization layer 109 and electrically connected with the second transfer electrode 242 through a seventh pixel via opened in the third planarization layer 109. The pixel definition layer 134 is disposed on the first electrode 131 and the third planarization layer 109, and the pixel definition layer 134 may be provided with a plurality of pixel openings, one pixel opening may expose at least part of a surface of a corresponding first electrode 131. At least portion of the organic emitting layer 132 may be disposed within one pixel opening and connected with a corresponding first electrode 131. The second electrode 133 may be disposed on the organic emitting layer 132 and be connected with the organic emitting layer 132. The organic emitting layer 132 may emit light of a corresponding color under drive of the first electrode 131 and the second electrode 133.

In some examples, the organic emitting layer 132 of the light emitting element may include an Emitting Layer (EML), and include at least one film layer of following: a Hole Injection Layer (HIL), a Hole Transport Layer (HTL), a Hole Block Layer (HBL), an Electron Block Layer (EBL), an Electron Injection Layer (EIL), and an Electron Transport Layer (ETL). Under drive of voltages of the first electrode 131 and the second electrode 133, light may be emitted according to a required gray scale, in virtue of light emitting characteristics of an organic material.

In some examples, emitting layers of light emitting elements of different colors may be different. For example, a red light emitting element includes a red emitting layer, a green light emitting element includes a green emitting layer, and a blue light emitting element includes a blue emitting layer. In order to reduce a process difficulty and improve a yield, a common layer may be adopted for a hole injection layer and a hole transport layer located on one side of an emitting layer, and a common layer may be adopted for an electron injection layer and an electron transport layer located on the other side of the emitting layer. In some examples, any one or more layers of the hole injection layer, the hole transport layer, the electron injection layer, and the electron transport layer may be made through one process (one evaporation process or one inkjet printing process), and isolation may be achieved by means of a formed film layer surface segment difference or by means of a surface treatment. For example, any one or more of hole injection layers, hole transport layers, electron injection layers, and electron transport layers corresponding to adjacent sub-pixels may be isolated. In some examples, the organic emitting layer may be prepared and formed through evaporation using a Fine Metal Mask (FMM) or an open mask, or prepared and formed using an inkjet process.

In some examples, as shown in FIG. 2, the encapsulation structure layer 14 may include a first encapsulation layer 141, a second encapsulation layer 142, and a third encapsulation layer 143 which are stacked. Herein, an inorganic material such as silicon nitride, silicon oxide, silicon oxynitride, or the like may be used for the first encapsulation layer 141 and the third encapsulation layer 143, and the inorganic material has high compactess and may prevent intrusion of water, oxygen, or the like. The second encapsulation layer 142 may be disposed between the first encapsulation layer 141 and the third encapsulation layer 143 to ensure that external water vapor cannot enter a light emitting element. An organic material may be adopted for the second encapsulation layer 142, for example, may be a polymer material containing a desiccant or a polymer material capable of blocking water vapor and the like, or a polymer resin or the like to planarize a surface of the display panel and relieve stress of the first encapsulation layer 141 and the third encapsulation layer 143, and may further include a water-absorbing material such as a desiccant to absorb substances such as water and oxygen invading the interior. However, the present embodiment is not limited thereto. For example, a five-layer stacked structure of inorganic/organic/inorganic/organic/inorganic may be adopted for an encapsulation structure layer.

In some examples, the touch structure layer 15 of the display region may include: a plurality of first touch electrodes, a plurality of first connection portions, a plurality of second touch electrodes, and a plurality of second connection portions. The plurality of first touch electrodes may be disposed in a same layer, and adjacent first touch electrodes may be connected through a first connection portion. The plurality of second touch electrodes may be disposed in a same layer, and adjacent second touch electrodes may be connected through a second connection portion.

In some examples, as shown in FIG. 2, in a direction perpendicular to the display panel, the touch structure layer 15 of the display region may include a Touch Buffer Layer (TBL) 150, a first touch conductive layer 151, a Touch interLayer Dielectric layer (TLD) 153, a second touch conductive layer 152, and a protective layer 154 disposed sequentially. The display panel of the present example may include two touch conductive layers. Herein, the touch buffer layer 150 and the touch interlayer dielectric layer 153 may be inorganic insulation layers, and the protective layer 154 may be an organic insulation layer. For example, the first touch conductive layer 151 may include a plurality of first touch electrodes, a plurality of second touch electrodes, and a plurality of first connection portions. A first touch control electrode and a first connection portion may be of an interconnected integral structure. The second touch conductive layer 152 may include a plurality of second connection portions. A second connection portion may be connected with an adjacent second touch electrode through a via opened in the touch interlayer dielectric layer. However, the present embodiment is not limited thereto. In other examples, the first touch conductive layer may include: a plurality of first touch electrodes, a plurality of second touch electrodes, and a plurality of second connection portions, and a second touch electrode and a second connection portion may be of an interconnected integral structure. The second touch conductive layer may include a plurality of first connection portions, and a first connection portion may be interconnected with an adjacent first touch electrode through a via opened in the touch interlayer dielectric layer. In some examples, the first touch control electrodes may be drive (Tx) electrodes and the second touch control electrodes may be sensing (Rx) electrodes. Or, the first touch electrodes may be sensing (Rx) electrodes and the second touch electrodes may be drive (Tx) electrodes. The present embodiment is not limited thereto.

In some examples, a first touch control electrode and a second touch control electrode may have a rhombus shape, such as a regular rhombus, a horizontally longer rhombus, or a vertically longer rhombus. In other examples, a first touch electrode and a second touch electrode may have any one or more of shapes of a triangle, a square, a trapezoid, a parallelogram, a pentagon, a hexagon, and another polygon, which is not limited in the embodiments of the present disclosure.

In some examples, a first touch electrode and a second touch electrode may be in a form of transparent conductive electrodes. In some other examples, a first touch electrode and a second touch electrode may be in a form of a metal grid. The metal grid may be formed by a plurality of interweaved metal lines, and may include a plurality of grid patterns. The grid patterns may be polygons formed by a plurality of metal lines. The first touch electrodes and the second touch electrodes in the form of the metal grid have advantages of small resistance, small thickness, fast response speed, and the like.

In some examples, as shown in FIG. 1, the first bezel region B1 may include a first fan-out region B11, a bending region B12 (which may also be referred to as a bendable portion), and a second fan-out region B13 (which may also be referred to as an extension portion), which are sequentially disposed along a direction away from the display region AA. The first fan-out region B11 may be connected with the display region AA, the first fan-out region B11 may be communicated with the second bezel region B2, and the bending region B12 may be communicated with the first fan-out region B11 and the second fan-out region B13. The bending region B12 may be configured to enable the second fan-out region B13 to be bent to a back surface of the display region AA. The second fan-out region B13 may be provided with a plurality of first contact pads connected with the drive chip and a plurality of second contact pads connected with the flexible circuit board, and the plurality of second contact pads may be located on a side of the plurality of first contact pads away from the bending region B12.

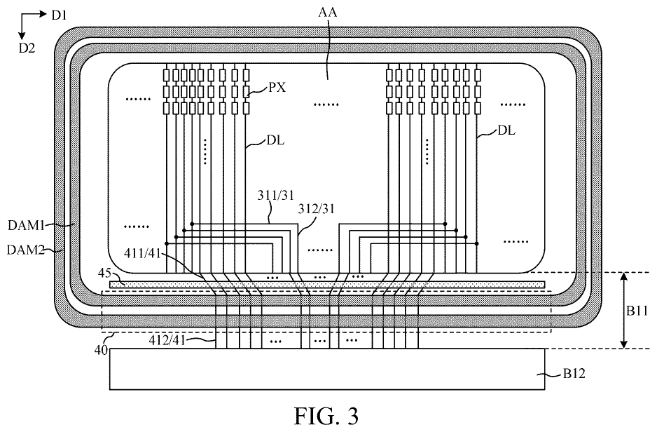

FIG. 3 is a schematic partial structural diagram of a display region and a first fan-out region according to at least one embodiment of the present disclosure. In some examples, as shown in FIG. 3, the display region AA may be provided with a plurality of sub-pixels PX, a plurality of data lines DL, and a plurality of data transfer lines 31. The plurality of sub-pixels PX are electrically connected with the plurality of data lines DL. The plurality of data lines DL may extend along the second direction D2 and be arranged along the first direction D1. A data transfer line 31 may include a first transfer segment 311 extending along the first direction D1 and a second transfer segment 312 extending along the second direction D2. Second transfer segments 312 of the data transfer lines 31 may be arranged between the plurality of data lines DL at intervals. A data line DL is connected with a first transfer segment 311 of a data transfer line 31, and the first transfer segment 311 is connected with a second transfer segment 312. The data line DL may be located on a side of the second transfer segment 312 of the connected data transfer line 31 close to an edge of the display panel in the first direction D1. A second transfer segment 312 of a data transfer line 31 may extend to the first fan-out region B11 and be connected with a data fan-out line 41 in the first fan-out region B11.

In some examples, the plurality of data lines DL may include a first set of data lines and a second set of data lines, the first set of data lines may directly extend to the first fan-out region B11 and be connected with a corresponding plurality of data fan-out lines 41, and the second set of data lines may be connected with a plurality of data fan-out lines 41 through a plurality of data transfer lines 31. Herein, the first set of data lines may be located on a side of the second set of data lines close to an edge of the display panel. However, the present embodiment is not limited thereto. In other examples, each of the plurality of data lines in the display region may achieve a connection with a data fan-out line through a data transfer line.

In this example, by achieving a connection between a data line and a data fan-out line through a data adapter line, data fan-out lines obliquely disposed in the first fan-out region may be reduced, and an inclination angle of a data fan-out line may be reduced, thereby facilitating reduction of a length of the first fan-out region along the second direction D2, so that a light leakage region in the first bezel region may be reduced accordingly, and a screen-to-body ratio may be improved, which is beneficial to achieving full-screen display.

In some examples, as shown in FIG. 3, the first fan-out region B11 may be provided with an isolation slot 40, a first dam spacer DAM1 (which may also be referred to as a first dam adhesive) located at least partially within the isolation slot 40, and a second dam spacer DAM2 (which may also be referred to as a second dam adhesive) located at least partially within the isolation slot 40. The isolation slot 40 extends at least along the first direction D1 in the first fan-out region B11. The first dam spacer DAM1 may extend toward the second bezel region to form an annular dam surrounding the display region AA. The second dam spacer DAM2 may extend toward the second bezel region to form an annular dam surrounding the display region AA. In the first fan-out region B11, the isolation slot 40, the first dam spacer DAM1, and the second dam spacer DAM2 may all extend along the first direction D1. The first dam spacer DAM1 may be located on a side of the second dam spacer DAM2 close to the display region AA, and in the first fan-out region B11, the second dam spacer DAM2 may be located on a side of the first dam spacer DAM1 close to the bending region B12. In some examples, the isolation slot 40 may be formed by removing an organic insulation layer, and the first dam spacer DAM1 and the second dam spacer DAM2 may be formed by retaining a partial region of an organic insulation layer within the isolation slot 40.

In some examples, as shown in FIG. 3, a data fan-out line 41 within the first fan-out region B11 may include a first extension segment 411 and a second extension segment 412 connected with each other. The first extension segment 411 may be located on a side of the second extension segment 412 close to the display region AA. The first extension segment 411 may be directly connected with a data line DL, or may be connected with a second transfer segment 312 of a data transfer line 31. The second extension segment 412 may extend toward the bending region B12 and be connected with a data bending line disposed in the bending region B12. Extension directions of the first extension segment 411 and the second extension segment 412 intersect. For example, the second extension segment 412 may extend along the second direction D2, and an extension direction of the first extension segment 411 intersects with both the first direction D1 and the second direction D2. The first extension segment 411 may also be referred to as an oblique extension segment, and the second extension segment 412 may also be referred to as a vertical extension segment. A distance between first extension segments 411 of adjacent data fan-out lines 41 may be smaller than a distance between second extension segments 412 of the adjacent data fan-out lines 41.

In some examples, a minimum included angle between an orthographic projection of a first extension segment 411 of at least one data fan-out line 41 on the base substrate and an orthographic projection of the first dam spacer DAM1 on the base substrate may be less than or equal to a minimum included angle between an orthographic projection of a second extension segment 412 of the at least one data fan-out line 41 on the base substrate and the orthographic projection of the first dam spacer DAM1 on the base substrate. For example, the first dam spacer DAM1 extends along the first direction D1, and the minimum included angle between the orthographic projection of the first extension segment 411 on the base substrate and the orthographic projection of the first dam spacer DAM1 on the base substrate may be a clockwise included angle or a counterclockwise included angle between the first extension segment 411 and the first direction D1, for example, the included angle may be less than 90 degrees. The minimum included angle between the orthographic projection of the second extension segment 412 on the base substrate and the orthographic projection of the first dam spacer DAM1 on the base substrate may be a clockwise or counterclockwise included angle between the second extension segment 412 and the first direction D1, for example, the included angle may be about 90 degrees.

In some examples, as shown in FIG. 3, connection positions of the first extension segments 411 and the second extension segments 412 of the plurality of data fan-out lines 41 may be located on a side of the second dam spacer DAM2 close to the display region AA. Orthographic projections of the connection positions of the first extension segments 411 and the second extension segments 412 of the plurality of data fan-out lines 41 on the base substrate may not be overlapped with an orthographic projection of the second dam spacer DAM2 on the base substrate. For example, an orthographic projection of a connection position of a first extension segment 411 and a second extension segment 412 of at least one data fan-out line 41 on the base substrate may be located within a range of the orthographic projection of the first dam spacer DAM1 on the base substrate, or may be located on a side of the first dam spacer DAM1 close to the display region AA. In this example, by reducing a length of a first extension segment 411 of a data fan-out line 41 and increasing a length of a second extension segment 412 of the data fan-out line 41, it is advantageous to increase an interval (Space) between adjacent data fan-out lines 41, thereby reducing a risk of reflection between adjacent data fan-out lines and reducing a risk of light leakage of the first bezel region.

In some examples, as shown in FIG. 3, a first light shielding structure 45 may be located on a side of the plurality of data fan-out lines 41 away from the base substrate. An orthographic projection of the first light shielding structure 45 on the base substrate may have a long strip shape extending along the first direction D1. The orthographic projection of the first light shielding structure 45 on the base substrate may be overlapped with orthographic projections of the first extension segments 411 of the plurality of data fan-out lines 41 on the base substrate, for example, the orthographic projection of the first light shielding structure 45 on the base substrate is partially overlapped with an orthographic projection of a first extension segment 411 of each data fan-out line 41 on the base substrate. The first light shielding structure 45 may be located on a side of the isolation slot 40 close to the display region AA, and not be overlapped with an orthographic projection of the isolation slot 40 on the base substrate.

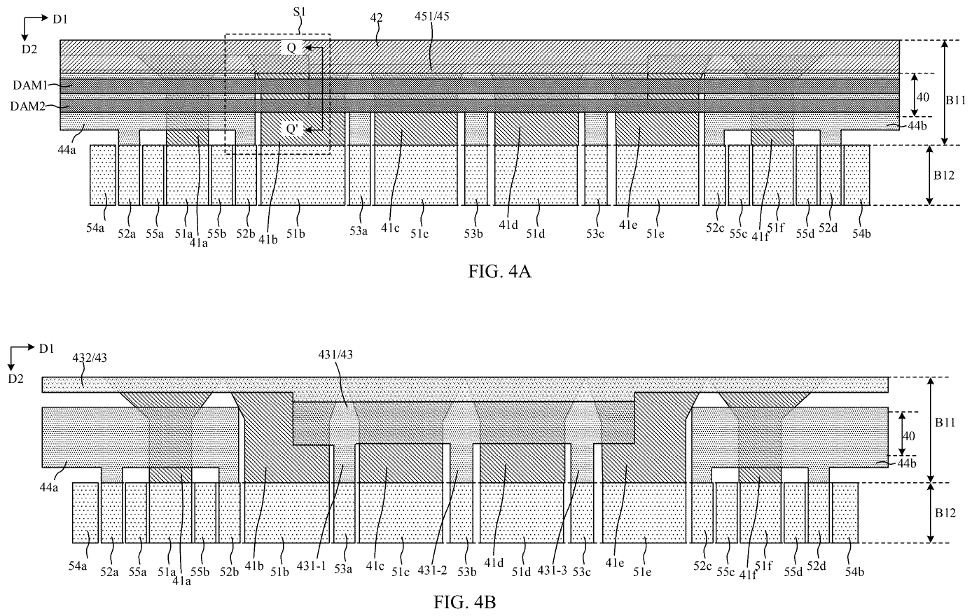

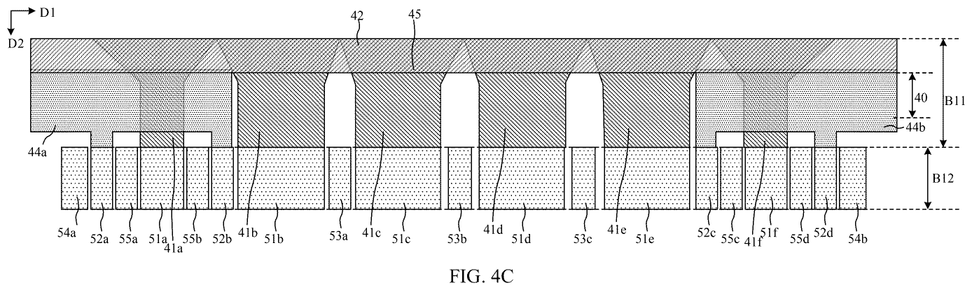

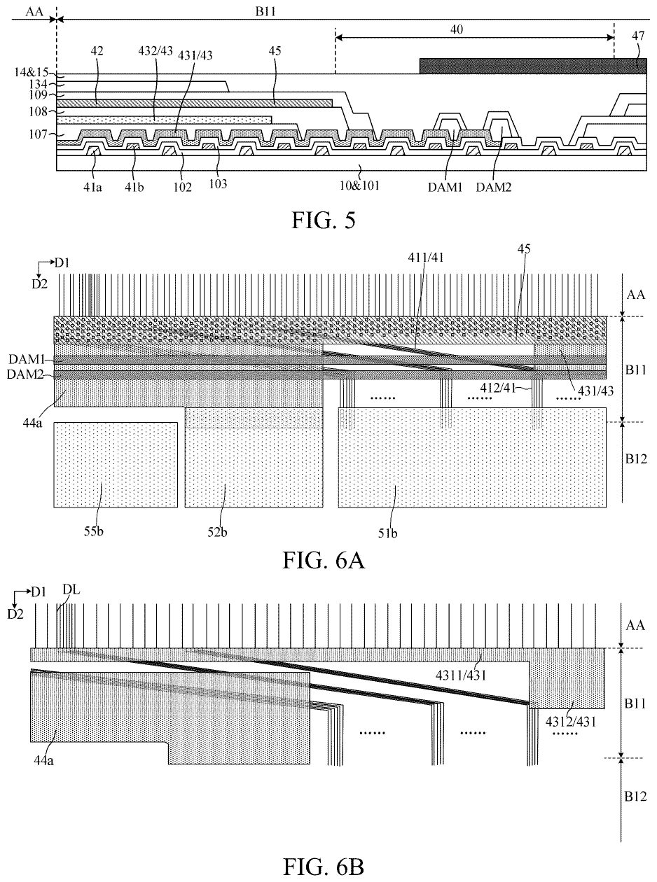

FIG. 4A is a schematic diagram of a trace arrangement of a first fan-out region and a bending region according to at least one embodiment of the present disclosure. FIG. 4B and FIG. 4C are schematic partial structural diagrams of the first fan-out region in FIG. 4A. In FIG. 4A to FIG. 4C, a plurality of sets of data fan-out lines of the first fan-out region and a plurality of sets of data bending lines of the bending region are schematically illustrated as a whole. FIG. 4A to FIG. 4C only simply illustrate an arrangement mode of the plurality of sets of data fan-out lines, and specific morphology of the plurality of sets of data fan-out lines are not limited in the present embodiment. FIG. 4B mainly illustrates a position and a structure of a second bezel power supply line, and FIG. 4C mainly illustrates positions and structures of a first bezel power supply line and a first light shielding structure. FIG. 5 is a schematic partial sectional view along a Q-Q′ direction in FIG. 4A.

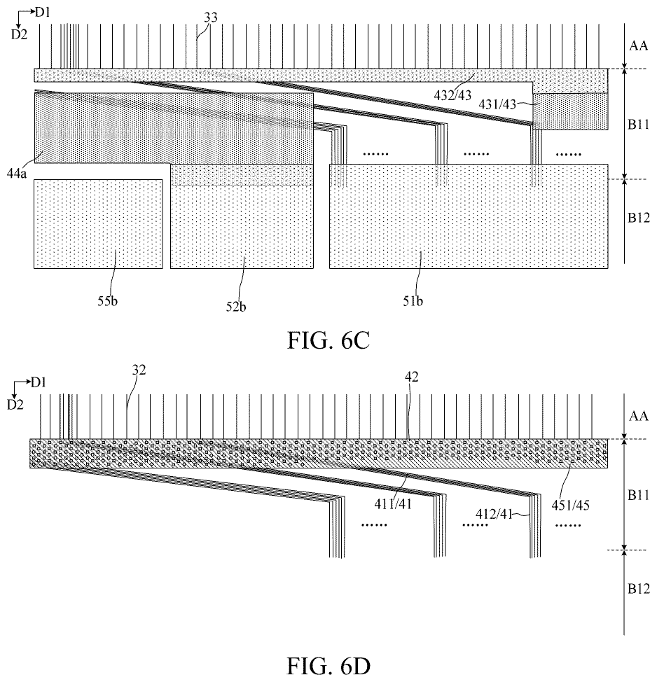

FIG. 6A is a partial enlarged schematic diagram of a region S1 in FIG. 4A. FIG. 6B is a schematic diagram of a first gate metal layer, a second gate metal layer, and a first source-drain metal layer in FIG. 6A. FIG. 6C is a schematic diagram of the first gate metal layer, the second gate metal layer, the first source-drain metal layer, and a second source-drain metal layer in FIG. 6A. FIG. 6D is a schematic diagram of the first gate metal layer, the second gate metal layer, and a third source-drain metal layer in FIG. 6A. In FIG. 6A to FIG. 6D, a second set of touch bending lines 55b, a second set of first power supply bending lines 52b, and a second set of data bending lines 51b are schematically illustrated as a whole.

In some examples, as shown in FIG. 4A to FIG. 4C, the plurality of data fan-out lines of the first fan-out region B11 may include six sets of data fan-out lines, for example, including a first set of data fan-out lines 41a, a second set of data fan-out lines 41b, a third set of data fan-out lines 41c, a fourth set of data fan-out lines 41d, a fifth set of data fan-out lines 41e, and a sixth set of data fan-out lines 41f. The first set of data fan-out lines 41a, the second set of data fan-out lines 41b, the third set of data fan-out lines 41c, the fourth set of data fan-out lines 41d, the fifth set of data fan-out lines 41e, and the sixth set of data fan-out lines 41f may be sequentially arranged along the first direction D1. In this example, by dividing a plurality of data fan-out lines into a plurality of sets, it is beneficial to reduce a length of an oblique extension segment, and is beneficial to reduce a reflection risk between adjacent data fan-out lines, and reduce a risk of light leakage of the first bezel region.

In some examples, as shown in FIG. 5, adjacent data fan-out lines may be located in different conductive layers. The plurality of data fan-out lines may include: a plurality of first data fan-out lines 41a located in the first gate metal layer and a plurality of second data fan-out lines 41b located in the second gate metal layer. The plurality of first data fan-out lines 41a and the plurality of second data fan-out lines 41b may be alternately disposed one by one. An interval between orthographic projections of a first data fan-out line 41a and a second data fan-out line 41b which are adjacent on the base substrate may be greater than zero. In other words, the orthographic projections of the first data fan-out line 41a and the second data fan-out line 41b which are adjacent on the base substrate may not be overlapped. The present embodiment is not limited thereto. In other examples, the plurality of data fan-out lines may be all disposed on the first gate metal layer, or, all disposed on the second gate metal layer.

In some examples, at least one data fan-out line may include a first extension segment 411 and a second extension segment 412 connected with each other. The first extension segment 411 and the second extension segment 412 may be of an interconnected integral structure.

In some examples, as shown in FIG. 4A to FIG. 6D, the first fan-out region B11 may be further provided with a first light shielding structure 45, a first bezel power supply line 42, a second bezel power supply line 43, and third bezel power supply lines 44a and 44b. The first bezel power supply line 42 is configured to supply a first voltage signal to a plurality of sub-pixels of the display region AA. The second bezel power supply line 43 may be configured to supply a second voltage signal to a plurality of sub-pixels of the display region AA. The second voltage signal may be greater than the first voltage signal. For example, the second voltage signal may be a high-level signal and the first voltage signal may be a low-level signal. The first bezel power supply line 42 may be connected with a plurality of low-potential power supply lines 32 of the display region AA, and the second bezel power supply line 43 may be connected with a plurality of high-potential power supply lines 33 of the display region AA. For example, the plurality of low-potential power supply lines 32 may be located in the third source-drain metal layer, and the plurality of high-potential power supply lines 33 may be located in the second source-drain metal layer. The first bezel power supply line 42 may be connected with the third bezel power supply lines 44a and 44b in the first bezel region or the second bezel region.

In some examples, as shown in FIG. 4A to FIG. 5, the first bezel power supply line 42 and the first light shielding structure 45 may be located on a side of the second bezel power supply line 43 away from the base substrate. The first bezel power supply line 42 may extend along the first direction D1 in the first fan-out region B11. The first light shielding structure 45 may be located on a side of the first bezel power supply line 42 away from the display region AA. The first light shielding structure 45 may be located on a side of the isolation slot 40 close to the display region AA. In other words, in the second direction D2, the first light shielding structure 45 may be located between the first bezel power supply line 42 and the isolation slot 40. The first light shielding structure 45 may include a light shielding sheet 451. A length of the light shielding sheet 451 extending along the first direction D1 may be longer than a length of the light shielding sheet 451 extending along the second direction D2.

In some examples, the first bezel power supply line 42 and the first light shielding structure 45 may be of a same layer structure, for example, both located in the third source-drain metal layer. The first bezel power supply line 42 is connected with the light shielding sheet 451 of the first light shielding structure 45, for example, the first bezel power supply line 42 and the light shielding sheet 451 of the first light shielding structure 45 are of an interconnected integral structure. As shown in FIG. 5, the light shielding sheet 451 may be disposed on the second planarization layer 108, and a surface of the light shielding sheet 451 close to the base substrate is in contact with the second planarization layer 108, so that flatness of the light shielding sheet 451 may be ensured, and an orthographic projection of the light shielding sheet 451 on the base substrate is overlapped with orthographic projections of the plurality of data fan-out lines on the base substrate, so that light leakage caused by reflection caused by uneven film layers in which the data fan-out lines are located may be shielded.

In some examples, as shown in FIG. 6D, the integral structure of the first bezel power supply line 42 and the light shielding sheet 451 may be provided with a plurality of vias penetrating through the entire integral structure along a direction perpendicular to a main surface of the base substrate to increase air permeability of the integral structure. In a case in which the light shielding sheet is made of a conductive material such as a metal or an alloy, air permeability thereof is poor, and by providing a plurality of vias, it may prevent problems such as water vapor emitted by a film layer below the light shielding sheet 451, especially an organic film layer (such as the second planarization layer 108), cannot be eliminated under conditions of heat and moisture, etc., and thus it may avoid resulting problems such as deformation and warpage of a film layer inside the display panel. In some examples, the plurality of vias on the light shielding sheet 451 may be arranged in a regular array, which may be beneficial to improve uniformity of air permeability and reduce a manufacturing difficulty. In other examples, the plurality of vias on the light shielding sheet 451 may be irregularly arranged.

In some examples, the second bezel power supply line 43 may include: a first sub power supply line 431 located in a first source-drain metal layer and a second sub power supply line 432 located in a second source-drain metal layer. An orthographic projection of the first sub power supply line 431 of the second bezel power supply line 43 on the base substrate and an orthographic projection of the second sub power supply line 432 on the base substrate may be at least partially overlapped. For example, the orthographic projection of the first sub power supply line 431 of the second bezel power supply line 43 on the base substrate may cover the orthographic projection of the second sub power supply line 432 on the base substrate. The second sub power supply line 432 may be located on a side of the isolation slot 40 close to the display region AA, and the orthographic projection of the second sub power supply line 432 on the base substrate may not be partially overlapped with an orthographic projection of the isolation slot 40 on the base substrate. In the first fan-out region B11, an orthographic projection of the integral structure of the first bezel power supply line 42 and the first light shielding structure 45 on the base substrate may cover the orthographic projection of the second sub power supply line 432 on the base substrate.

In some examples, the second sub power supply line 432 may be provided with a plurality of vias penetrating through the entire second sub power supply line 432 along a direction perpendicular to a main surface of the base substrate, so as to increase air permeability of the second sub power supply line 432 and prevent problems such as water vapor emitted by a film layer below the second sub power supply line 432, especially an organic film layer (such as the first planarization layer 107), cannot be eliminated under conditions of heat and moisture, etc., and so as to avoid resulting problems such as deformation and warpage of a film layer inside the display panel.

In some examples, as shown in FIG. 4B and FIG. 6B, the first sub power supply line 431 located in the first source-drain metal layer may include: a first power supply main body portion 4311, a first power supply extension portion 4312 extending from the first power supply main body portion 4311 to a side away from the display region AA, and three power supply connection portions 431-1, 431-2, and 431-3 extending from the first power supply extension portion 4312 to the bending region B12. The three power supply connection portions 431-1, 431-2, and 431-3 may be arranged at intervals, and may be connected with three sets of second power supply bending lines in the bending region B12 in one-to-one correspondence. The orthographic projection of the first sub power supply line 431 on the base substrate and the orthographic projection of the isolation slot 40 on the base substrate may be overlapped; for example, orthographic projections of the first power supply extension portion 4312 and the three power supply connection portions 431-1, 431-2, and 431-3 of the first sub power supply line 431 on the base substrate may be partially overlapped with the orthographic projection of the isolation slot 40 on the base substrate. The first power supply main body portion 4311 of the first sub power supply line 431 extends along the first direction D1, and an orthographic projection of the first power supply main body portion 4311 on the base substrate may be located within a range of the orthographic projection of the second sub power supply line 432 on the base substrate.

In some examples, the third bezel power supply lines 44a and 44b and the first sub power supply line 431 may be of a same layer structure, for example, the third bezel power supply lines 44a and 44b may be located in the first source-drain metal layer. The third bezel power supply lines 44a and 44b may be located on a side of the first sub power supply line 431 of the second bezel power supply line 43 away from the display region AA. The third bezel power supply lines 44a and 44b may be located on both sides of the first power supply extension portion 4312 of the first sub power supply line 431 of the second bezel power supply line 43 along the first direction D1. The third bezel power supply line 44a may extend to a left bezel region of the second bezel region, and the third bezel power supply line 44b may extend to a right bezel region of the second bezel region. An orthographic projection of the third bezel power supply line 44a on the base substrate may be overlapped with orthographic projections of the first set of data fan-out lines 41a on the base substrate, and an orthographic projection of the third bezel power supply line 44b on the base substrate may be overlapped with orthographic projections of the sixth set of data fan-out lines 41f on the base substrate. The orthographic projections of the third bezel power supply lines 44a and 44b on the base substrate may be overlapped with the orthographic projection of the isolation slot 40 on the base substrate. For example, the third bezel power supply lines 44a and 44b may be connected with the first bezel power supply line 42 through the first light shielding structure 45. However, the present embodiment is not limited thereto. In other examples, the third bezel power supply lines 44a and 44b may be directly connected with the first bezel power supply line 42 at connection corners of the first bezel region and the second bezel region.

In some examples, as shown in FIG. 4A to FIG. 4C, the bending region B12 may be provided with a plurality of sets of data bending lines, including, for example, a first set of data bending lines 51a, a second set of data bending lines 51b, a third set of data bending lines 51c, a fourth set of data bending lines 51d, a fifth set of data bending lines 51e, and a sixth set of data bending lines 51f. Each set of data bending lines may include a plurality of data bending lines. The first set of data bending lines 51a may be connected with the first set of data fan-out lines 41a, the second set of data bending lines 51b may be connected with the second set of data fan-out lines 41b, the third set of data bending lines 51c may be connected with the third set of data fan-out lines 41c, the fourth set of data bending lines 51d may be connected with the fourth set of data fan-out lines 41d, the fifth set of data bending lines 51e may be connected with the fifth set of data fan-out lines 41e, and the sixth set of data bending lines 51f may be connected with the sixth set of data fan-out lines 41f.

In some examples, the bending region B12 may further be provided with a plurality of sets of first power supply bending lines (e.g., including a first set of first power supply bending lines 52a, a second set of first power supply bending lines 52b, a third set of first power supply bending lines 52c, and a fourth set of first power supply bending lines 52d), a plurality of sets of second power supply bending lines (e.g., including a first set of second power supply bending lines 53a, a second set of second power supply bending lines 53b, and a third set of second power supply bending lines 53c), a plurality of sets of control bending lines (e.g., a first set of control bending lines 54a, and a second set of control bending lines 54b), and a plurality of sets of touch bending lines (e.g., including a first set of touch bending lines 55a, a second set of touch bending lines 55b, a third set of touch bending lines 55c, and a fourth set of touch bending lines 55d). Each set of first power supply bending lines may include: at least one first power supply bending line. Each set of second power supply bending lines may include at least one second power supply bending line. Each set of control bending lines may include a plurality of control bending lines. Each set of touch bending lines may include a plurality of touch bending lines.

In some examples, the first set of control bending lines 54a, the first set of first power supply bending lines 52a, the first set of touch bending lines 55a, the first set of data bending lines 51a, the second set of touch bending lines 55b, the second set of first power supply bending lines 52b, the second set of data bending lines 51b, the first set of second power supply bending lines 53a, the third set of data bending lines 51c, the second set of second power supply bending lines 53b, the fourth set of data bending lines 51d, the third set of second power supply bending lines 53c, the fifth set of data bending lines 51e, the third set of first power supply bending lines 52c, the third set of touch bending lines 55c, the sixth set of data bending lines 51f, the fourth set of touch bending lines 55d, the fourth set of first power supply bending lines 52d, and the second set of control bending lines 54b may be disposed sequentially along the first direction D1. Herein, the first set of data bending lines 51a may be located between two sets of first power supply bending lines, and the sixth set of data bending lines 51f may be located between two sets of first power supply bending lines. The second set of data bending lines 51b to the fifth set of data bending lines 51e and three sets of second power supply bending lines may be arranged alternatively at intervals. A trace setting method of this example is beneficial to reduce a length of an oblique trace of a data fan-out line.

In some examples, a plurality of bending lines of the bending region B12 may be located in a same conductive layer, for example, may be located in the second source-drain metal layer. The present embodiment is not limited thereto. In other examples, the plurality of bending lines of the bending region may be located in the first source-drain metal layer or the second source-drain metal layer.

In some examples, as shown in FIG. 5, the first planarization layer 107, the second planarization layer 108, and the third planarization layer 109 within the isolation slot 40 may be removed. The first dam spacer DAM1 may be formed by stacking a plurality of dam foundations, for example, may be formed by stacking a first dam foundation in a same layer as the second planarization layer 108, a second dam foundation in a same layer as the third planarization layer 109, and a third dam foundation in a same layer as the pixel definition layer 134. The second dam spacer DAM2 may be formed by stacking a plurality of dam foundations, for example, may be formed by stacking a first dam foundation in a same layer as the first planarization layer 107, a second dam foundation in a same layer as the second planarization layer 108, a third dam foundation in a same layer as the third planarization layer 109, and a fourth dam foundation in a same layer as the pixel definition layer 134. The present embodiment is not limited thereto. In other examples, a third dam spacer may be disposed on a side of the second dam spacer away from the first dam spacer.

In some examples, as shown in FIG. 5, the display panel may further include a light shielding layer 47 located on a side of the encapsulation layer 14 and the touch structure layer 15 away from the base substrate. An orthographic projection of the light shielding layer 47 on the base substrate and the orthographic projection of the isolation slot 40 on the base substrate may be at least partially overlapped, for example, the orthographic projection of the light shielding layer 47 on the base substrate may cover the orthographic projection of the isolation slot 40 on the base substrate. A distance between orthographic projections of the light shielding layer 47 and the first light shielding structure 45 on the base substrate is greater than 0, i.e., the orthographic projections of the light shielding layer 47 and the first light shielding structure 45 on the base substrate are not overlapped. A material of the light shielding layer 47 may be a light-opaque organic material, for example, may be ink. As a result, a light leakage phenomenon of the first bezel region may be improved by matching the first light shielding structure 45 with the light shielding layer 47.

In other examples, the first light shielding structure may include a plurality of light shielding sheets independently disposed sequentially along the first direction, and the plurality of light shielding sheets may be connected with the first bezel power supply line. Or, at least one light shielding sheet of the plurality of light shielding sheets is connected with the first bezel power supply line, and at least one light shielding sheet is connected with the second bezel power supply line. Or, each of the plurality of light shielding sheets may be connected with the second bezel power supply line. For example, a light shielding sheet may be located in the third source-drain metal layer and connected with the first sub power supply line or the second sub power supply line of the second bezel power supply line exposed by the isolation slot through a connection electrode. The present embodiment is not limited thereto.

In other examples, the first light shielding structure may include: a plurality of light shielding sheets, and the plurality of light shielding sheets may be of a same layer structure, for example, all located in the second source-drain metal layer or the third source-drain metal layer; or, the plurality of light shielding sheets may be disposed in a plurality of source-drain metal layers, for example, one part of the plurality of light shielding sheets may be located in the second source-drain metal layer, and the other part of the light shielding sheets may be located in the third source-drain metal layer. In other examples, a planarization layer may be provided on a side of the first source-drain metal layer close to the base substrate, and a plurality of light shielding sheets of the first light shielding structure may be located in the first source-drain metal layer, or may be located in the first source-drain metal layer and the second source-drain metal layer, or may be located in the first source-drain metal layer, the second source-drain metal layer, and the third source-drain metal layer.

In other examples, a material of the first light shielding structure may be a light-opaque organic material, such as a black resin material. The first light shielding structure may be located on the third planarization layer 109, for example, the first light shielding structure may be prepared after the pixel definition layer 134, or may be prepared before the pixel definition layer 134. The first light shielding structure may be a monolithic structure extending along the first direction, or may be a plurality of block structures arranged along the first direction. However, the present embodiment is not limited thereto. In other examples, the first light shielding structure may be located on the second planarization layer or the first planarization layer.

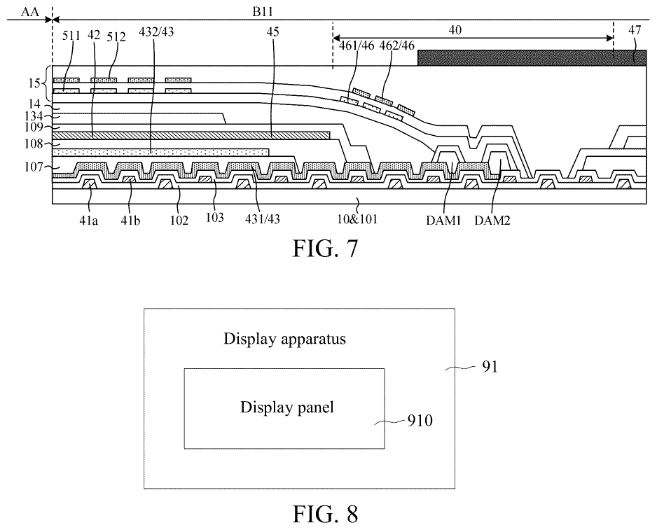

FIG. 7 is another schematic partial sectional view of a first fan-out region according to at least one embodiment of the present disclosure. In some examples, the display panel may further include a second light shielding structure 46 located in the first fan-out region B11. The second light shielding structure 46 may be located on a side of the first light shielding structure 45 away from the display region AA. Orthographic projections of the second light shielding structure 46 and the first light shielding structure 45 on the base substrate may not be overlapped. An orthographic projection of the second light shielding structure 46 on the base substrate and the orthographic projection of the isolation slot 40 on the base substrate may be at least partially overlapped. For example, the orthographic projection of the second light shielding structure 46 on the base substrate may be located within a range of the orthographic projection of the isolation slot 40 on the base substrate. Orthographic projections of the second light shielding structure 46 and the light shielding layer 47 on the base substrate may be partially overlapped or may not be overlapped.

In some examples, the first touch conductive layer of the first fan-out region B11 may include a first touch lead-out line 511, and the second touch conductive layer may include a second touch lead-out line 512. The second light shielding structure 46 may include a first light shielding block 461 located in the first touch conductive layer and a second light shielding block 462 located in the second touch conductive layer. Orthographic projections of the first light shielding block 461 and the second light shielding block 462 on the base substrate may be partially overlapped, or may not be overlapped. At least one of the first light shielding block 461 and the second light shielding block 462 may be floating and do not transmit an electrical signal; or, at least one of the first light shielding block 461 and the second light shielding block 462 may be connected with a ground line. The present embodiment is not limited thereto. In other examples, the second light shielding structure may include at least one first light shielding block located in the first touch conductive layer, or may include at least one second light shielding block located in the second touch conductive layer.

Rest of a structure of the display panel of the example may be referred to description of the aforementioned embodiments, and thus will not be repeated here.

In this example, through a matching arrangement of the first light shielding structure, the second light shielding structure, and the light shielding layer, a light leakage region of the first fan-out region may be effectively shielded, thereby improving a light leakage problem of the display panel.

FIG. 8 is a schematic diagram of a display apparatus according to at least one embodiment of the present disclosure. As shown in FIG. 8, the embodiment provides a display apparatus 91 including a display panel 910 of the aforementioned embodiments. In some examples, the display panel 910 may be an OLED display panel, such as an OLED display panel with an integrated touch structure. The display apparatus 91 may be any product or component having a display function, such as a mobile phone, a tablet computer, a television, a display, a notebook computer, a digital photo frame, or a navigator, or may be a product or component having touch and display functions.

In description of the specification, reference terms such as “an embodiment”, “some embodiments”, “an example” or “some examples” mean that a particular feature, structure, material, or characteristic described in connection with the embodiment or example is included in at least one embodiment or example of the present disclosure. In the specification, schematic expressions of the above terms are not necessarily aimed at a same embodiment or example. Moreover, the specific feature, structure, material, or characteristic described may be combined in a proper mode in any one or more embodiments or examples. In addition, if there is no conflict, those skilled in the art may integrate and combine different embodiments or examples and features of different embodiments or examples described in the specification.

Although the embodiments of the present application have been shown and described above, it should be understood that the above embodiments are exemplary, but cannot be understood as limitations on the present application. Alterations, modifications, substitutions, and variations may be made to the above embodiments by those skilled in the art within the scope of the present application.

1. A display panel, comprising:
a base substrate comprising a display region and a first bezel region located on at least one side of the display region; wherein the first bezel region comprises a first fan-out region and a bending region disposed sequentially along a direction away from the display region;
a plurality of sub-pixels located in the display region;
a plurality of data lines located in the display region and electrically connected with the plurality of sub-pixels;
a plurality of data fan-out lines located in the first fan-out region and electrically connected with the plurality of data lines, and configured to provide data signals to the plurality of sub-pixels of the display region; and
a first light shielding structure located in the first fan-out region, wherein the first light shielding structure is located on a side of the plurality of data fan-out lines away from the base substrate, and an orthographic projection of the first light shielding structure on the base substrate is partially overlapped with orthographic projections of the plurality of data fan-out lines on the base substrate.

2. The display panel according to claim 1, further comprising: an isolation slot located in the first fan-out region; wherein the first light shielding structure is located on a side of the isolation slot close to the display region, and a distance between the orthographic projection of the first light shielding structure on the base substrate and an orthographic projection of the isolation slot on the base substrate is greater than 0.

3. The display panel according to claim 2, further comprising: a first dam spacer at least partially located within the isolation slot and a second dam spacer at least partially located within the isolation slot, wherein the second dam spacer is located on a side of the first dam spacer away from the display region; and
at least one data fan-out line of the plurality of data fan-out lines comprises a first extension segment and a second extension segment connected with each other, the first extension segment is located on a side of the second extension segment close to the display region, and extension directions of the first extension segment and the second extension segment intersect; a distance between first extension segments of two adjacent data fan-out lines is less than or equal to a distance between second extension segments of the two adjacent data fan-out lines; and a connection position of the first extension segment and the second extension segment is located on a side of the second dam spacer close to the display region.

4. The display panel according to claim 3, wherein a minimum included angle between an orthographic projection of the first extension segment of the at least one data fan-out line on the base substrate and an orthographic projection of the first dam spacer on the base substrate is less than or equal to a minimum included angle between an orthographic projection of the second extension segment on the base substrate and the orthographic projection of the first dam spacer on the base substrate.

5. The display panel according to claim 1, wherein the first light shielding structure comprises at least one light shielding sheet, a length of the light shielding sheet in a direction from the display region to the first bezel region is smaller than a length extending along an edge of the display region, and the light shielding sheet is provided with a plurality of vias penetrating through the light shielding sheet along a direction perpendicular to the base substrate.

6. The display panel according to claim 1, further comprising: a first bezel power supply line located in the first fan-out region, wherein the first bezel power supply line is configured to provide a first voltage signal to a plurality of sub-pixels of the display region; and
the first light shielding structure is connected with the first bezel power supply line.

7. The display panel according to claim 6, wherein the first light shielding structure comprises at least one light shielding sheet, and the at least one light shielding sheet and the first bezel power supply line are of an interconnected integral structure.

8. The display panel according to claim further comprising: a second bezel power supply line located in the first fan-out region, wherein the second bezel power supply line is configured to provide a second voltage signal to a plurality of sub-pixels of the display region, and the second voltage signal is greater than the first voltage signal; and
the second bezel power supply line is located on a side of the first bezel power supply line close to the base substrate and located on a side of the plurality of data fan-out lines away from the base substrate, and an orthographic projection of the second bezel power supply line on the base substrate is partially overlapped with an orthographic projection of the first bezel power supply line on the base substrate.

9. The display panel according to claim 1, further comprising: at least one planarization layer, wherein a surface of the first light shielding structure close to the base substrate is in contact with a planar surface of the planarization layer.

10. The display panel according to claim 9, wherein in a direction perpendicular to the display panel, the display panel comprises at least: a first source-drain metal layer, a second source-drain metal layer, and a third source-drain metal layer sequentially disposed on the base substrate; the first light shielding structure is located on at least one of following film layers: the first source-drain metal layer, the second source-drain metal layer, and the third source-drain metal layer.

11. The display panel according to claim 1, further comprising: an encapsulation layer and a light shielding layer; wherein the encapsulation layer is located on a side of the first light shielding structure away from the base substrate, and the light shielding layer is located on a side of the encapsulation layer away from the base substrate; a distance between an orthographic projection of the light shielding layer on the base substrate and the orthographic projection of the first light shielding structure on the base substrate is greater than 0; and a material of the light shielding layer is a light-opaque organic material.

12. The display panel according to claim 1, further comprising: a second light shielding structure located in the first fan-out region and located on a side of the first light shielding structure away from the display region; wherein the second light shielding structure is located on a side of the first light shielding structure away from the base substrate.

13. The display panel according to claim 12, wherein in a direction perpendicular to the display panel, the display panel comprises: a plurality of display conductive layers and at least one touch conductive layer sequentially disposed on the base substrate; and
the first light shielding structure is located in one display conductive layer of the plurality of display conductive layers, and the second light shielding structure is located in the at least one touch conductive layer.

14. The display panel according to claim 1, further comprising: a plurality of data transfer lines located in the display region, wherein at least one data transfer line of the plurality of data transfer lines comprises: a first transfer segment extending along a first direction and a second transfer segment extending along a second direction, the plurality of data lines extend along the second direction, and the first direction intersects with the second direction; at least one data line of the plurality of data lines is connected with the first transfer segment of the data transfer line, the second transfer segment of the data transfer line is connected with the data fan-out lines, and the data line is located on a side of the second transfer segment of the connected data transfer line close to an edge of the display panel in the first direction.

15. The display panel according to claim 1, further comprising: a plurality of sets of data bending lines located in the bending region and disposed separately, wherein the plurality of data fan-out lines comprise a plurality of sets of data fan-out lines, and the plurality of sets of data fan-out lines are connected with the plurality of sets of data bending lines in a one-to-one correspondence.

16. A display apparatus, comprising a display panel according to claim 1.

17. The display panel according to claim 7, further comprising: a second bezel power supply line located in the first fan-out region, wherein the second bezel power supply line is configured to provide a second voltage signal to a plurality of sub-pixels of the display region, and the second voltage signal is greater than the first voltage signal; and
the second bezel power supply line is located on a side of the first bezel power supply line close to the base substrate and located on a side of the plurality of data fan-out lines away from the base substrate, and an orthographic projection of the second bezel power supply line on the base substrate is partially overlapped with an orthographic projection of the first bezel power supply line on the base substrate.

18. A display apparatus, comprising a display panel according to claim 2.

19. A display apparatus, comprising a display panel according to claim 5.

20. A display apparatus, comprising a display panel according to claim 6.
